(19) United States
(12) Patent Application Publication
(10) Pub. No.: US 2022/0316090 A1
(43) Pub. Date: Oct. 6, 2022

(54) METHOD FOR GROWING EPITAXIAL LAYER ON WAFER

(71) Applicant: SK Siltron Co., LTD., Gyeongsangbuk-do (KR)

(72) Inventors: Dong Ho KANG, Gyeongsangbuk-do (KR); Kun Young KIM, Gyeongsangbuk-do (KR)

(21) Appl. No.: 17/693,517

(22) Filed: Mar. 14, 2022

(30) Foreign Application Priority Data
Mar. 30, 2021 (KR) 10-2021-0041234

(51) Int. Cl. C30B 25/10; H01L 21/02

(52) U.S. Cl. CPC C30B 25/105; H01L 21/02658; H01L 21/02532; H01L 21/02634; H01L 21/0262; H01L 21/02598; H01L 21/02381; H01L 21/68742

(57) ABSTRACT

Embodiments provide a method of growing an epitaxial layer on a wafer, the method including steps of (a) introducing at least one wafer into a process chamber, (b) loading the wafer into an area adjacent to a susceptor while supporting the wafer using a lift pin, (c) preheating the wafer, and (d) placing the wafer in a pocket of the susceptor and heating the wafer to deposit an epitaxial layer on the wafer, wherein outputs of first lamps above the susceptor and second lamps under the susceptor in the steps (a) and (b) are set to be different from outputs of the first lamps and the second lamps in the steps (c) and (d).

### CROSS-REFERENCE TO RELATED PATENT APPLICATIONS

This application claims the benefit of Korean Patent Application No. 10-2021-0041234, filed on Mar. 30, 2021, which is hereby incorporated by reference as if fully set forth herein.

### BACKGROUND OF THE INVENTION

### Field of the Invention

Embodiments relate to a method of growing an epitaxial layer on a wafer, and more particularly to a method of alleviating warpage of the wafer during a process of growing the epitaxial layer so as to prevent the incidence of large dislocation pits (LDP) and local light scattering (LLS).

### Discussion of the Related Art

A wafer, such as a single crystal silicon wafer, is subjected to various processes such as depositing a layer of a predetermined material on a surface of the wafer, etching the layer of the predetermined material on the surface, or heat-treating the entire wafer. These processes may be divided into a batch-type process, in which multiple wafers are accommodated in a chamber serving as a reactor and processed at the same time, and a single-type process, in which only one wafer is processed at a time.

In the single-type process, a wafer is seated on a susceptor or on a chuck so as to be processed, and there is known a wafer-processing apparatus having a structure of lifting a bottom surface of the wafer using a wafer lift pin through a through hole, formed in a predetermined portion of the susceptor, when seating the wafer on the susceptor or when separating the processed wafer from the susceptor.

For vapor-phase growth of a layer of a predetermined material on a wafer using such a processing apparatus, the layer of the predetermined material may be vapor-grown after the wafer is loaded into a chamber while being supported by a lift pin.

However, the conventional method of growing an epitaxial layer on a wafer has the following problems.

At a portion of a bottom surface of a wafer lifted using a lift pin, there may be generated a kind of contamination or defect called a pin mark. Considering that such a pin mark is frequently generated in a process involving high-temperature heat (e.g., epitaxial growth, heat treatment, etc.), it is assumed that the pin mark is generated because temperature uniformity in the wafer deteriorates due to local heat loss caused by the lift pin. Also, the pin mark may be caused by a silicon layer or particles on a surface of the lift pin.

In addition, when a wafer at room temperature is introduced into a process chamber at high temperature, occurrence of large dislocation pits (LDP) due to warpage may increase, and local light scattering (LLS) may also increase. Here, “LLS” is a generic term for defects observed by light scattering, among defects analyzed using a laser, and LLS may be all defects on the wafer surface observed by scattering.

In order to reduce the incidence of the above-described defects on a wafer, there have been attempts to change the loading temperature depending on the type of the wafer or to improve loading time.

However, no attempt has been made to control the warpage of the wafer by adjusting an output balance of a lamp in the process chamber.

### SUMMARY OF THE INVENTION

Accordingly, the present invention is directed to a method of growing an epitaxial layer on a wafer that substantially obviates one or more problems due to limitations and disadvantages of the related art.

An object of the present invention is to provide a method of adjusting an output balance of a lamp in a process chamber in order to reduce the incidence of large dislocation pits (LDP) and local light scattering (LLS) due to warpage of a wafer.

Additional advantages, objects, and features of the invention will be set forth in part in the description which follows and in part will become apparent to those having ordinary skill in the art upon examination of the following, or may be learned from practice of the invention. The objectives and other advantages of the invention may be realized and attained by the structures particularly pointed out in the written description and claims hereof as well as the appended drawings.

To achieve these objects and other advantages and in accordance with the purpose of the invention, as embodied and broadly described herein, a method of growing an epitaxial layer on a wafer includes steps of (a) introducing at least one wafer into a process chamber, (b) loading the wafer into an area adjacent to a susceptor while supporting the wafer using a lift pin, (c) preheating the wafer, and (d) placing the wafer in a pocket of the susceptor and heating the wafer to deposit an epitaxial layer on the wafer, wherein outputs of first lamps above the susceptor and second lamps under the susceptor in the steps (a) and (b) are set to be different from outputs of the first lamps and the second lamps in the steps (c) and (d).

A sum of the outputs of the first lamps and the second lamps in the steps (c) and (d) may be set to be greater than a sum of the outputs of the first lamps and the second lamps in the steps (a) and (b).

The first lamps may include first-1 lamps in a central area and first-2 lamps in an edge area, and the second lamps may include second-1 lamps in a central area and second-2 lamps in an edge area. An output ratio of the first-1 lamps in the steps (a) and (b) may be set to be the same as an output ratio of the first-1 lamps in the steps (c) and (d).

The output ratio of the first-1 lamps may be set to 48% to 86% in the steps (a) to (d).

The first lamps may include first-1 lamps in a central area and first-2 lamps in an edge area, and the second lamps may include second-1 lamps in a central area and second-2 lamps in an edge area. An output ratio of the second lamps in the steps (a) and (b) may be set to be different from an output ratio of the second lamps in the steps (c) and (d).

The output ratio of the second lamps may be set to 30% to 90% in the steps (a) and (b), and the output ratio of the second lamps may be set to 50% to 62% in the steps (c) and (d).

The first lamps may include first-1 lamps in a central area and first-2 lamps in an edge area, and the second lamps may include second-1 lamps in a central area and second-2 lamps in an edge area. An output ratio of the second-1 lamps in the steps (a) and (b) may be set to be different from an output ratio of the second-1 lamps in the steps (c) and (d).

The output ratio of the second-1 lamps may be set to 11.5% to 21% in the steps (a) and (b), and the output ratio of the second-1 lamps may be set to 11.5% to 25% in the steps (c) and (d).

Warpage of the wafer may be observed through a wafer vision area of the process chamber in the steps (a) to (d).

The wafer may be warped upwards in each of the steps (a) and (c).

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a flowchart of a method of growing an epitaxial layer on a wafer according to an embodiment;

FIG. 2 shows the relative positions of a wafer, a susceptor, and a lift pin in each step in FIG. 1;

FIG. 3 is a view illustrating an apparatus for growing an epitaxial layer on a wafer according to an embodiment;

FIG. 4 shows the result of a method of growing an epitaxial layer on a wafer according to an embodiment; and

FIG. 5 shows the result of a method of growing an epitaxial layer on a wafer according to a comparative embodiment.

### DETAILED DESCRIPTION OF THE INVENTION

Hereinafter, embodiments of the present invention will be described in detail with reference to the accompanying drawings.

The embodiments of the present invention may be modified into various forms, and the scope of the present invention should not be construed as being limited to the following embodiments. These embodiments are provided so that this disclosure will be thorough and complete, and will fully convey the scope of the disclosure to those skilled in the art.

In addition, relative terms such as, for example, “first”, “second”, “on/upper/above”, and “beneath/lower/below”, used in the following description may be used to distinguish any one substance or element from another substance or element without requiring or implying any physical or logical relationship or sequence between these substances or elements.

A silicon wafer may be prepared by performing a grinding process of processing an outer circumferential surface of a single crystal silicon ingot grown using the Czochralski method or the like, a slicing process of thinly cutting the single crystal silicon ingot into wafers, a lapping process of polishing the wafer to a desired thickness to improve flatness, an etching process of removing a damaged layer from the wafer, and a polishing process for surface mirror finish and improvement of flatness, and by finally performing a cleaning process, a process of forming an oxide film, and a rapid thermal process or the like, to be described later, to remove contaminants from the surface of the wafer.

An epitaxial wafer is fabricated by growing an epitaxial layer, which is another single-crystal film, on the surface of the polished wafer grown in such a way. Here, the epitaxial wafer may have fewer surface defects than the polished wafer, and may be capable of controlling the concentration or type of impurities. In addition, the epitaxial layer has high purity and excellent crystallinity, and thus may have advantages of increasing the yield and improving the characteristics of a highly integrated semiconductor device.

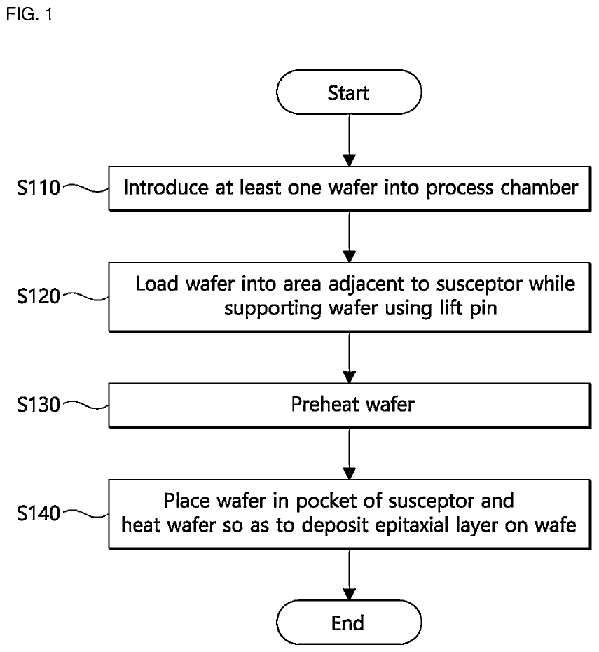

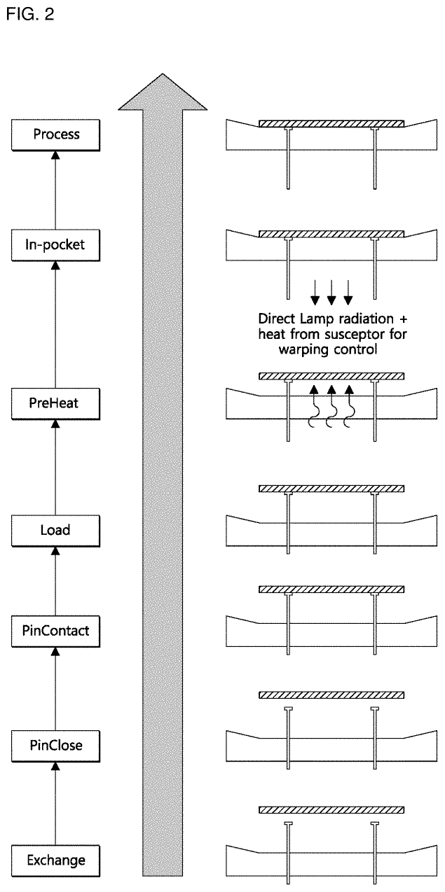

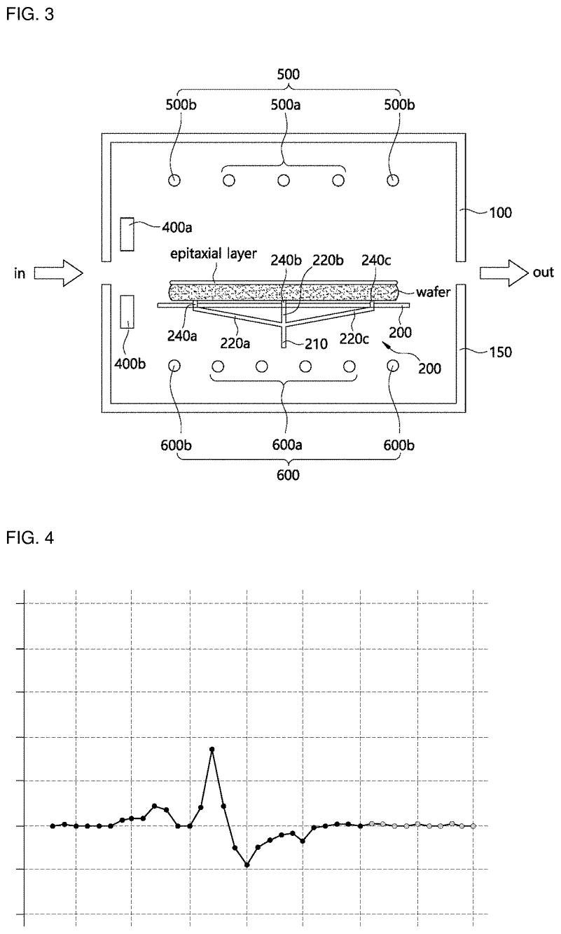

FIG. 1 is a flowchart of a method of growing an epitaxial layer on a wafer according to an embodiment, FIG. 2 shows the relative positions of a wafer, a susceptor, and a lift pin in each step in FIG. 1, and FIG. 3 is a view illustrating an apparatus for growing an epitaxial layer on a wafer according to an embodiment. Hereinafter, a method of growing an epitaxial layer on a wafer according to an embodiment will be described with reference to FIGS. 1 to 3.

In the apparatus used in the method of growing an epitaxial layer on a wafer according to the embodiment, an epitaxial layer may be grown on a wafer, which is disposed on a susceptor 200 that is disposed inside a process chamber, and first lamps 500 and second lamps 600 may be respectively disposed in an upper portion and a lower portion of the process chamber, as illustrated in FIG. 3. In addition, thermometers 400a and 400b may be respectively provided in the upper portion and the lower portion of the process chamber, but the embodiment is not limited thereto.

The susceptor 200 may include a main shaft 210 serving as a central axis, three support shafts 220a, 220b, and 220c extending from the main shaft 210 toward the edge of the wafer, and first to third lift pins 240a, 240b, and 240c disposed at ends of the three support shafts 220a, 220b, and 220c so as to support the wafer, but the embodiment is not limited thereto.

The process chamber may include an upper dome 100 and a lower dome 150, which are respectively provided above and under the susceptor 200 and the first to third lift pins 240a, 240b, and 240c. Here, the area inside the upper dome 100 and the area inside the lower dome 150 may form a space for growing an epitaxial layer. In addition, a gas inlet (in) and a gas outlet (out) may be formed in the process chamber so as to form a film such as an epitaxial layer on the surface of the wafer.

Although not illustrated, a wafer vision area may be provided in the upper dome 100, and warpage of the wafer during a process of depositing an epitaxial layer may be observed through the wafer vision area.

A carrier gas such as hydrogen and/or a source gas (or reactant gas) such as silane (SiHCl₃ or SiH₂Cl₂) needed for growing an epitaxial layer on the wafer may be introduced through the gas inlet (in) to form an epitaxial layer on the wafer, and residual gas may be discharged through the gas outlet (out) after forming the epitaxial layer. As illustrated, the gas inlet (in) and the gas outlet (out) may be formed to face each other, but the embodiment is not limited thereto.

Moreover, since the susceptor 200 is provided between the gas inlet (in) and the gas outlet (out), and since the gas inlet (in) and the gas outlet (out) are positioned at substantially the same height as the upper surface of the susceptor 200, the source gas introduced through the gas inlet (in) may flow on the surface of the wafer.

In order to control the temperature inside the process chamber, light is discharged from the first lamp 500 and the second lamp 600, respectively disposed above and under the susceptor 200, to the upper area and the lower area of the susceptor 200, respectively, and radiant heat discharged from the first lamp 500 and the second lamp 600 may be transferred to the wafer. Here, the first lamp 500 may be referred to as an up lamp, and the second lamp 600 may be referred to as a bottom lamp.

The first lamp 500 provided in the upper area of the susceptor 200 may be divided into a first-1 lamp 500a provided in a central area and a first-2 lamp 500b provided in an edge area, and the second lamp 600 provided in the lower area of the susceptor 200 may be divided into a second-1 lamp 600a provided in a central area and a second-2 lamp 600b provided in an edge area.

In a method of growing an epitaxial layer on a wafer according to an embodiment, the output of the lamps described above is adjusted in steps of introducing a wafer into a process chamber, loading the wafer, preheating the wafer, and depositing an epitaxial layer. This will be described below in detail.

First, at least one wafer is introduced into a process chamber in step S110.

In FIG. 2, a process (an exchange process) of taking the wafer, on which the epitaxial layer deposition process has been completed, out of the process chamber and introducing a new wafer into the process chamber is performed first. Thereafter, a lift pin is brought close to the bottom surface of the wafer (PinClose), and the lift pin is brought into contact with the bottom surface of the wafer (PinContact) to support the wafer.

Then, the wafer is loaded into an area adjacent to a susceptor while the wafer is supported using the lift pin in step S120. In FIG. 2, the lift pin supporting the wafer is lowered so as to load the wafer into the area adjacent to the susceptor.

A combination of the above-described introduction and loading steps may be referred to as a process of transferring a wafer, and a combination of preheating and deposition processes, which will be described later, may be referred to as a heating process. In addition, as will be described later, the output of the lamps in the process of transferring the wafer may be different from the output of the lamps in the heating process. For example, in the transfer process, the ambient temperature of the wafer may be set to 800° C., and in the heating process, the ambient temperature of the wafer may be set to 900° C.

Here, the outputs of the first lamps and the second lamps may be maintained the same in the above-described introduction and loading steps. However, the outputs of the first lamps and the second lamps in the introduction and loading steps may be different from the outputs of the first lamps and the second lamps in the preheating and deposition processes, to be described later. Specifically, a sum of the outputs of the first lamps and the second lamps in the preheating and deposition processes may be set to be greater than a sum of the outputs of the first lamps and the second lamps in the introduction and loading steps. For example, a total output of the first lamp and the second lamp may be 30 kw (kilowatts) in the introduction and loading steps, and a total output of the first lamp and the second lamp in the preheating and deposition steps may be 60 kw.

Here, an output ratio of the first-1 lamps in the introduction and loading steps may be set to be the same as an output ratio of the first-1 lamps in the preheating and deposition steps. For example, the output ratio of the first-1 lamps may be maintained at 48% to 86%. Here, when the output ratio of the fist-1 lamps is 48% to 86%, it means that the output ratio of the first-1 lamps accounts for 48% to 86% of the total output of the first lamps.

Then, the wafer is preheated in step S130. As shown in FIG. 2, in the process of preheating, the wafer is brought close to the susceptor but is spaced apart from the susceptor, and the process of depositing the epitaxial layer to be described later may be performed after the wafer is brought into contact with the susceptor so as to be inserted into the pocket (in-pocket).

Then, the wafer is placed in the pocket of the susceptor and heated to deposit the epitaxial layer on the wafer in step S140.

In the preheating and deposition processes, in addition to the direct transfer of the radiant heat discharged from the first lamps and the second lamps to the wafer, the heat discharged from the heated susceptor may be transferred to the wafer, resulting in warpage of the wafer, particularly in an upward direction.

In addition, the output ratio of the second lamps in the above-described introduction and loading steps may be set to be different from the output ratio of the lamps in the above-described preheating and deposition steps. For example, the output ratio of the second lamps may be set to 30% to 90% in the introduction and loading steps, and the output ratio of the second lamps may be set to 50% to 62% in the preheating and deposition steps. Here, when the output ratio of the second lamps is 30% to 90%, it means that the output ratio of the second lamps accounts for 30% to 90% of the total output of the first lamps and the second lamps. When the output ratio of the second lamps is 50% to 62%, it means that the output ratio of the second lamps accounts for 50% to 62% of the total output of the first lamps and the second lamps.

In addition, the output ratio of the second-1 lamps in the above-described introduction and loading steps may be set to be different from the output ratio of the second-1 lamps in the above-described preheating and deposition steps. For example, the output ratio of the second-1 lamps may be set to 11.5% to 21% in the above-described introduction and loading steps, and the output ratio of the second-1 lamps may be set to 11.5% to 25% in the above-described steps of preheating and loading. Here, when the output ratio of the second-1 lamps is 11.5% to 21%, it means that the output ratio of the second-1 lamps accounts for 11.5% to 21%, of the total output of the second lamps. When the output ratio of the second-1 lamps is 11.5% to 25%, it means that the output ratio of the second-1 lamps accounts for 11.5% to 25% of the total output of the second lamps.

During the introduction, loading, preheating, and deposition processes described above, warpage of the wafer may be observed through the wafer vision area described above. For example, the wafer may be warped upwards in FIG. 3. When warpage of the wafer is observed, the output of the lamps described above may be readjusted.

Before the wafer is loaded onto the susceptor, warpage of the wafer may occur due to the radiant heat of the lamp, etc., and in the preheating and deposition processes after the loading process, defects may be generated by heat transfer owing to the wafer being in contact with the susceptor, in addition to warpage due to the radiant heat of the lamp.

In the embodiment, the output of the lamps in the processes of introducing and loading a wafer is set to be different from the output of the lamps in the processes of preheating and depositing a wafer, and warpage of the wafer is observed in real time through the wafer vision area of the process chamber so as to set the outputs to be different from each other, thereby reducing defects such as warpage of the wafer.

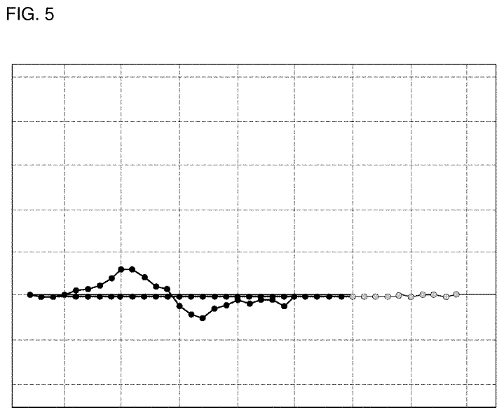

FIG. 4 shows the result of a method of growing an epitaxial layer on a wafer according to an embodiment, and FIG. 5 shows the result of a method of growing an epitaxial layer on a wafer according to a comparative embodiment.

As in the embodiment, when the output of the lamps in the transfer process is set to be different from the output of the lamps in the heating process while the epitaxial layer is grown on the wafer, warpage of the wafer may be alleviated compared to when the outputs of the lamps are set to be the same. In addition, even when the outputs of the lamp are set to be different from each other in each of the transfer process and the heating process, a wafer with reduced warpage may be obtained when the conditions according to the above-described embodiment are followed.

In FIG. 4, the output ratio of the second lamps is set to 30%, the output ratio of the first-2 lamps is set to 77%, and the output ratio of the second-1 lamps is set to 25% in the transfer process, and the output ratio of the second lamps is set to 50%, the output ratio of the first-2 lamps is set to 48%, and the output ratio of the second-1 lamps is set to 21% in the heating process.

In FIG. 5, the output ratio of the second lamps is set to 58%, the output ratio of the first-2 lamps is set to 86%, and the output ratio of the second-1 lamps is set to 9.5% in the transfer process, and the output ratio of the second lamps is set to 50%, the output ratio of the first-2 lamps is set to 60%, and the output ratio of the second-1 lamps is set to 14.5% in the heating process.

As shown, according to the method of growing the epitaxial layer on the wafer in the embodiment of FIG. 4, a wafer in which the output ratios of the lamps are controlled in the transfer process and in the heating process exhibits reduced warpage compared to a wafer fabricated by the process according to the comparative embodiment of FIG. 5.

According to the method of growing the epitaxial layer on the wafer according to the embodiment, when the output of the lamps in the transfer process is set to be different from the output of the lamps in the heating process, warpage of the wafer may be alleviated compared to when the outputs of the lamps are set to be the same. In addition, even when the outputs of the lamps are set to be different in each of the transfer process and the heating process, a wafer with reduced warpage may be obtained when following the conditions according to the above-described embodiment.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method of growing an epitaxial layer on a wafer, the method comprising steps of:
(a) introducing at least one wafer into a process chamber;
(b) loading the wafer into an area adjacent to a susceptor while supporting the wafer using a lift pin;
(c) preheating the wafer; and
(d) placing the wafer in a pocket of the susceptor and heating the wafer to deposit an epitaxial layer on the wafer,
wherein outputs of first lamps above the susceptor and second lamps under the susceptor in the steps (a) and (b) are set to be different from outputs of the first lamps and the second lamps in the steps (c) and (d).

2. The method according to claim 1, wherein a sum of the outputs of the first lamps and the second lamps in the steps (c) and (d) is set to be greater than a sum of the outputs of the first lamps and the second lamps in the steps (a) and (b).

3. The method according to claim 1, wherein the first lamps comprise first-1 lamps in a central area and first-2 lamps in an edge area, and the second lamps comprise second-1 lamps in a central area and second-2 lamps in an edge area, and
wherein an output ratio of the first-1 lamps in the steps (a) and (b) is set to be the same as an output ratio of the first-1 lamps in the steps (c) and (d).

4. The method according to claim 3, wherein the output ratio of the first-1 lamps is set to 48% to 86% in the steps (a) to (d).

5. The method according to claim 1, wherein the first lamps comprise first-1 lamps in a central area and first-2 lamps in an edge area, and the second lamps comprise second-1 lamps in a central area and second-2 lamps in an edge area, and
wherein an output ratio of the second lamps in the steps (a) and (b) is set to be different from an output ratio of the second lamps in the steps (c) and (d).

6. The method according to claim 5, wherein the output ratio of the second lamps is set to 30% to 90% in the steps (a) and (b), and the output ratio of the second lamps is set to 50% to 62% in the steps (c) and (d).

7. The method according to claim 1, wherein the first lamps comprise first-1 lamps in a central area and first-2 lamps in an edge area, and the second lamps comprise second-1 lamps in a central area and second-2 lamps in an edge area, and
wherein an output ratio of the second-1 lamps in the steps (a) and (b) is set to be different from an output ratio of the second-1 lamps in the steps (c) and (d).

8. The method according to claim 7, wherein the output ratio of the second-1 lamps is set to 11.5% to 21% in the steps (a) and (b), and the output ratio of the second-1 lamps is set to 11.5% to 25% in the steps (c) and (d).

9. The method according to claim 1, wherein warpage of the wafer is observed through a wafer vision area of the process chamber in the steps (a) to (d).
